(19) United States
(12) Patent Application Publication
(10) Pub. No.: US 2017/0217814 A2
(43) Pub. Date: Aug. 3, 2017

(54) METHOD FOR PRODUCING A BLANK FROM TITANIUM- AND FLUORINE-DOPED GLASS HAVING A HIGH SILICIC-ACID CONTENT

(71) Applicants: Stefan OCHS, Gelnhausen (DE); Klaus BECKER, Hanau (DE)

(72) Inventors: Stefan OCHS, Gelnhausen (DE); Klaus BECKER, Hanau (DE)

(73) Assignee: Heraeus Quarzglas GmbH & Co. KG, Hanau (DE)

(21) Appl. No.: 15/035,776

(22) PCT Filed: Nov. 6, 2014
(86) PCT No.: PCT/EP2014/073921

§ 371 Date: May 11, 2016

(30) Foreign Application Priority Data
Nov. 12, 2013 (DE) 10 2013 112 396.1

(51) Int. Cl. C03B 19/14; C03C 4/00; G03F 1/24; C03C 3/06

(52) U.S. Cl. CPC C03B 19/1461; C03C 3/06; C03C 4/0085; G03F 1/24; C03B 2201/12; C03C 2201/42; C03C 2204/00

(57) ABSTRACT

A method for producing a blank from titanium-doped, highly silicic-acidic glass having a specified fluorine content for use in EUV lithography is described, in which the thermal expansion coefficient over the operating temperature remains at zero as stably as possible. The course of the thermal expansion coefficient of Ti-doped silica glass depends on a plurality of influencing factors. In addition to the absolute titanium content, the distribution of the titanium is of significant importance, as is the ratio and distribution of additional doping elements, such as fluorine. In the method, fluorine-doped TiO₂—SiO₂ soot particles are generated and processed further via consolidation and vitrifying into the blank, and, by flame hydrolysis of input substances containing silicon and titanium, TiO₂—SiO₂-soot particles are formed, exposed to a reagent containing fluorine in a moving powder bed, and converted to the fluorine-doped TiO₂—SiO₂-soot particles.

### CROSS-REFERENCE TO RELATED APPLICATIONS

This application is a Section 371 of International Application No. PCT/EP2014/073921, filed Nov. 6, 2014, which was published in the German language on May 21, 2015 under International Publication No. WO 2015/071167 A1 and the disclosure of which is incorporated herein by reference.

### BACKGROUND OF THE INVENTION

In EUV lithography, highly integrated structures with a line width of less than 50 nm are produced by microlithographic projection devices. Radiation from the EUV range (extreme ultraviolet light, also called soft X-ray radiation) is used at wavelengths of around 13 nm. The projection devices are equipped with mirror elements which consist of titanium dioxide-doped glass having a high silicic-acid content (hereinafter also called “TiO₂—SiO₂glass” or “Ti-doped silica glass”) and are provided with a reflective layer. These materials are distinguished by an extremely low linear coefficient of thermal expansion (shortly called “CTE”:coefficient of thermal expansion) which is adjustable through the concentration of titanium. Standard titanium-dioxide concentrations are between 6% by wt. and 9% by wt.

In the intended use of such blanks consisting of synthetic, titanium-doped glass with high silicic-acid content as the mirror substrate, the upper side thereof is provided with a reflective film. The maximum (theoretical) reflectivity of such an EUV mirror element is about 70%, so that at least 30% of the radiation energy is absorbed in the coating or in the near-surface layer of the mirror substrate and converted into heat. Within the volume of the mirror substrate this leads to an inhomogeneous temperature distribution with temperature differences that, according to the literature, may amount to 50° C.

For a deformation that is as small as possible, it would therefore be desirable if the glass of the mirror substrate blank had a CTE which is at zero over the whole temperature range of the working temperatures occurring during use. In fact, however, in Ti-doped silica glasses the temperature range with a CTE around zero is very limited.

The temperature at which the coefficient of thermal expansion of the glass is equal to zero shall also be called zero crossing temperature or T_{ZC} (Temperature of Zero Crossing) hereinafter. The titanium concentration is normally set such that one obtains a CTE of zero in the temperature range between 20° C. and 45° C. Volume regions of the mirror substrate with a higher or a lower temperature than the preset T_{ZC} expand or contract, resulting, despite an altogether low CTE of the TiO₂—SiO₂glass, in deformations that are detrimental to the imaging quality of the mirror.

In addition, the fictive temperature of the glass plays a role. The fictive temperature is a glass property that represents the degree of order of the “frozen” glass network. A higher fictive temperature of the TiO₂—SiO₂glass is accompanied by a lower degree of order of the glass structure and a greater deviation from the energetically most advantageous structural arrangement.

The fictive temperature is influenced by the thermal history of the glass, particularly by the last cooling process. In the last cooling process, there are bound to be other conditions for near-surface regions of a glass block than for central regions, so that different volume regions of the mirror substrate blank already have different fictive temperatures due to their different thermal history, which, in turn, correlate with correspondingly inhomogeneous regions with respect to the CTE curve. In addition, however, the fictive temperature is also influenced by the amount of fluorine as fluorine has an impact on the structural relaxation. Fluorine doping allows the setting of a lower fictive temperature and, as a consequence, also a smaller slope of the CTE curve against the temperature.

In principle, there are proposals about how to counteract the deterioration in optical imaging by inhomogeneous temperature distribution in a mirror substrate blank.

For instance, it is known from WO 2011/078414 A2 that in a blank for a mirror substrate or for a mask plate of SiO₂—TiO₂ glass, the concentration of titanium oxide over the thickness of the blank is adapted stepwise or continuously to the temperature distribution occurring during operation in such a manner that the condition for the zero crossing temperature T_{ZC} is satisfied at every point, i.e., the coefficient of thermal expansion for the locally evolving temperature is substantially equal to zero. A CTE is here defined to be substantially equal to zero if the remaining longitudinal expansion during operation is 0±50 ppb/° C. at every point. This is said to be accomplished in that during production of the glass by flame hydrolysis, the concentration of precursor substances containing titanium or silicon, respectively, is varied such that a predetermined concentration profile is set in the blank.

It is further known from US 2006/0179879 A1 that in a TiO₂—SiO₂glass for use in EUV lithography the CTE curve against the temperature evolving during operation can be influenced, apart from a homogeneous distribution of the titanium concentration, by further parameters, inter alia by doping with fluorine. According to this prior art, a porous TiO₂—SiO₂soot body which is deposited by flame hydrolysis of precursor substances containing silicon and titanium is acted upon with a fluorine reagent in a first embodiment and is subsequently vitrified. In another variant, which corresponds to the method of the aforementioned type, the fluorine is added as fluorine-containing precursor substance to the flame hydrolysis already during deposition of the TiO₂—SiO₂soot particles so that a SiO₂ soot powder with a fluorine-titanium co-doping is obtained and is subsequently vitrified and optionally subjected to further process steps.

Moreover, DE103 59 951 A1 (˜US 2004/0118155 A1) discloses fluorination of undoped SiO₂ soot particles. To this end, the SiO₂ soot particles have an inert gas stream flowing therethrough in a powder bed and are delivered by this stream to a burner which vitrifies the soot particles in a combustible gas flame and simultaneously dopes them with fluorine, owing to the supply of a fluorine reagent. The burner is arranged on a heated deposition chamber in which the SiO₂ particles which are fluorine-doped and vitrified are deposited and form a massive quartz-glass blank at this place.

The spatial CTE profile in a Ti-doped silica glass blank depends on several influencing factors. Apart from the absolute titanium content, the distribution of the titanium is of great importance, as are the amount and distribution of further doping elements, such as fluorine.

Although the CTE profile can be varied via the operating temperature by measures disclosed in the prior art by taking great adjusting efforts, and thermally induced mirror deformations can thereby be reduced, it is not always possible to avoid image errors. Especially, the inhomogeneous distribution of fluorine in blanks of titanium-doped silica glass according to the prior art still poses a problem.

### BRIEF SUMMARY OF THE INVENTION

The present invention refers to a method for producing a blank from titanium-doped glass having a high silicic-acid content with a predetermined fluorine content for use in EUV lithography, comprising a synthesis process in which fluorine-doped TiO₂—SiO₂soot particles are produced and processed by consolidation and vitrification into the blank.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1a is a schematic illustration of an arrangement for the batchwise execution of the method according to an embodiment of the invention;

FIG. 1b is a schematic illustration of an arrangement for the continuous execution of the method according to a further embodiment of the invention;

FIG. 2 is a diagram showing the CTE curve against the temperature (0° C. to 70° C.);

FIG. 3 is an illustration of the local distribution of the fluorine amount against the CA area of the blank; and

FIG. 4 is an illustration of the local distribution of the mean value deviation of the CTE against the CA area of the blank.

### DETAILED DESCRIPTION OF THE INVENTION

It is an object of the present invention to provide a method for producing a blank from a fluorine-doped TiO₂—SiO₂glass in which a particularly homogeneous distribution of the titanium and the fluorine in the glass is achieved.

This object is achieved according to the invention in that the synthesis process comprises a method step in which TiO₂—SiO₂soot particles are formed by flame hydrolysis of precursor substances containing silicon and titanium, and a subsequent method step in which the TiO₂—SiO₂soot particles are exposed in a moved powder bed to a fluorine-containing reagent and converted into the fluorine-doped TiO₂—SiO₂soot particles.

In the synthesis process by flame hydrolysis of precursor substances containing silicon and titanium, TiO₂—SiO₂soot particles are produced which, at a correspondingly high temperature in the deposition chamber, agglomerate on a substrate surface into a porous TiO₂—SiO₂soot body of low density. Due to the flow conditions, individual soot particles cannot reach the substrate surface or are entrained from there and form the so-called powder-like “soot waste” which is collected in corresponding filtering systems. The missing purity of the soot waste poses problems, as on the way to the filtering system and in the filtering system itself numerous contaminants may contact the soot particles.

However, if in the synthesis process the substrate surface is arranged in the process chamber for the deposition of the soot particles at an increased distance from the burner, or if the substrate surface is cooled in a targeted manner, the TiO₂—SiO₂soot particles remain substantially separated from one another and are obtained as powder on the substrate surface or in a collecting vessel.

Soot particles are open-structured agglomerates of rather small aggregates of primary particles according to DIN 53206 Sheet 1 (08/72) and have a great BET (Brunauer-Emmett-Teller) specific surface area, so that they can easily interact with one another and also with foreign substances.

The invention suggests that TiO₂—SiO₂soot particles should be collected in a moved powder bed and should be treated there with a fluorine-containing reagent. The movement of the powder bed, either due to external influence or by blowing in the fluorine reagent or another gas stream, achieves a slight turbulence of the fine soot particles, so that the fluorine reagent can optimally react with the TiO₂—SiO₂soot particles. In comparison with a soot body of agglomerated soot particles, where a certain amount of time is needed until the fluorine reagent also reaches the soot particles in the interior of the soot body, the fluorine can react with the individual soot particles in the moved powder bed within a very short period of time. The TiO₂—SiO₂soot particles are thereby doped with fluorine. In comparison with doping of a TiO₂—SiO₂soot body by action of a gaseous or liquid fluorine reagent according to the prior art, the distribution of the fluorine according to the method of the invention is much more homogeneous. Owing to the open structure of the agglomerated soot particles, the fluorine-containing reagent is given a maximum surface contact with the TiO₂—SiO₂soot particles, whereby the particularly homogeneous incorporation of fluorine in the TiO₂—SiO₂structure takes place. Even with fluorine doping directly during the deposition of the TiO₂—SiO₂soot particles, such a homogeneous distribution of the fluorine is not achieved as the reaction duration is here very short, and even slightest temperature variations during deposition have an impact on the distribution of the fluorine and also of the titanium in the soot particle.

With the method according to the invention, it is also possible to provide TiO₂—SiO₂soot particles already containing fluorine, by action of the fluorine reagent in the moved powder bed, with a higher and particularly homogeneously distributed fluorine doping. The turbulence of the TiO₂—SiO₂soot particles, which are possibly doped with fluorine, effects a homogenization of the distribution of the previously introduced doping elements as possible concentration differences in sub-quantities of the soot particles are thereby compensated.

The homogeneous distribution of the fluorine and of the titanium in the fluorinated TiO₂—SiO₂soot particles is a basic precondition that the desired blank of titanium-doped glass having a high silicic-acid content with a predetermined fluorine content for use in EUV lithography also shows a particularly homogeneous distribution of the two doping elements, resulting in an optimized profile of the CTE with a small slope against the operational temperature range.

Suitable modifications of the method according to the invention will now be explained in more detail.

It has turned out to be advantageous when octamethylcyclotetrasiloxane (OMCTS) is used as the silicon-containing precursor substance, and titanium isopropoxide [Ti(OPrⁱ)₄] as the titanium-containing precursor substance. OMCTS and titanium isopropoxide have turned out to be useful as chlorine-free feed materials for the formation of SiO₂—TiO₂ particles.

As an alternative, however, silicon tetrachloride (SiCl₄) in combination with titanium tetrachloride (TiCl₄) may be used. The conversion of SiCl₄ and other chlorine-containing feed materials produces hydrochloric acid which causes high costs in waste gas washing and disposal. Therefore, OMCTS and titanium isopropoxide are preferably used as chlorine-free feed materials; the combination of SiCl₄ with TiCl₄ within the meaning of the invention is however considered to be equivalent.

With respect to an advantageous reaction behavior of the TiO₂—SiO₂soot particles with the fluorine reagent, it has turned out to be useful when the TiO₂—SiO₂soot particles have a mean particle size in the range of 20 nm to 500 nm and a BET specific surface area in the range of 50 m²/g to 300 m²/g. Depending on the thermal-pyrogenic conditions, the soot particles contain nanoparticles as primary particles with particle sizes in the range of a few nanometers up to 100 nm. Typically, such nanoparticles have a BET specific surface area of 40-800 m²/g. By agglomeration of the primary particles in the deposition process with formation of the soot particles, one obtains a mean particle size in the range of 20 nm to 500 nm and a BET specific surface area in the range of 50 m²/g to 300 m²/g. Besides a pronounced reactivity, this characteristic of the TiO₂—SiO₂soot particles also has a favorable influence on the further processability during consolidation of the fluorine-doped TiO₂—SiO₂soot particles by granulation or/and pressing.

It has also turned out to be expedient if the TiO₂ content of the fluorine-doped TiO₂—SiO₂soot particles is set in the range of 6% by wt. to 12% by wt., and that the fluorine content of the fluorine-doped TiO₂—SiO₂soot particles is set in the range of 1,000 wt. ppm to 10,000 wt. ppm. A dopant content in these ranges is of importance to a small variation of the CTE and its profile against the operational temperature.

SiF₄, CHF₃, CF₄, C₂F₆, C₃F₈, F₂ or SF₆ is used as the fluorine-containing reagent. The selection of one of the aforementioned reagents mainly depends on economic aspects in process control. When SF₆ is used, one achieves simultaneous doping with sulfur and fluorine, with sulfur also having an advantageous influence on the zero expansion of the silica glass and on the CTE profile within the meaning of the invention.

A further advantageous development of the method according to the invention is that the moved powder bed is formed as a loose bulk material of TiO₂—SiO₂soot particles which has the fluorine-containing reagent flowing therethrough and is moved thereby. Owing to the loose bulk material of the TiO₂—SiO₂soot particles, the flow resistance for the gaseous fluorine-containing reagent is particularly low. The fluorine-containing reagent is thereby brought very rapidly into maximum surface contact with the TiO₂—SiO₂soot particles, whereby the particularly homogeneous incorporation of fluorine in the TiO₂—SiO₂structure takes place.

The action time of the fluorine-containing reagent on the TiO₂—SiO₂soot particles in the moved powder bed can be kept short. Preferably, the fluorine-containing reagent acts on the TiO₂—SiO₂soot particles for a duration of at least 5 minutes.

A further acceleration of the reaction of the fluorine reagent is achieved by heating the powder bed to a temperature in the range of room temperature (20° C. to about 25° C.) to not more than 1,100° C. Depending on the size of the volume of the powder bed, an economically efficient heating temperature is chosen for the powder bed. At a relatively small amount of soot particles, heating of the powder above room temperature may not be required because the fluorine doping process also takes place at any rate within an acceptable period of time. Furthermore, which fluorine-containing reagent is used plays a role in the setting of the temperature of the powder bed. A temperature above 1,100° C. is disadvantageous as a sintering of the TiO₂—SiO₂will then set in, which reduces the reactive surface of the soot particles, and the advantage of the particularly efficient and homogeneous fluorine doping of the loose soot particles is thereby frustrated.

Moreover, it has turned out to be advantageous when the movement of the powder bed includes a mechanical action. Although the powder bed is already moved by the fluorine-containing reagent flowing therethrough, an additional mechanical action intensifies this state of the powder bed. The mechanical action may, e.g., include a vibrating or circulating of the powder bed, with the circulation being accomplished by rotating a rotary tube containing the powder bed or by introducing agitators into the powder bed.

After the action of the fluorine-containing reagent on the TiO₂—SiO₂soot particles, consolidation takes place. It has turned out to be useful when the fluorine-doped TiO₂—SiO₂soot particles are consolidated by granulating and/or pressing. Granulating improves the properties for further processing. Standard drying or wet-granulating methods are possible; spray granulation is also encompassed. A further processing of the granulates is preferably carried out by pressing into a shaped body from which the desired blank for use in EUV lithography is formed by vitrification. Alternatively, the granulates may also be used in a slip which in the end also after corresponding shaping processes and vitrification leads to the blank of titanium-doped glass having a high silicic-acid content with a predetermined fluorine content for use in EUV lithography. As a rule, the consolidation of the fluorine-doped TiO₂—SiO₂soot particles is also possible by way of direct pressing, either in uniaxial or isostatic form, without previous granulation of the soot particles.

Due to a more or less high concentration of Ti³⁺ ions in the glass matrix, titanium-doped glass having a high silicic-acid content shows a brownish coloration which turns out to pose problems for the reason that standard optical measuring methods which require transparency in the visible spectral range can thus only be used to a limited degree, or cannot be used at all for such blanks. To avoid this coloration, the concentration of Ti³⁺ must be reduced in favor of Ti⁴⁺ prior to vitrification.

In this connection, it is advantageous to subject, prior to vitrification, the fluorine-doped TiO₂—SiO₂soot particles to a conditioning treatment which comprises an oxidizing treatment with a nitrogen oxide, oxygen or ozone. The Ti-doped silica glass to be produced according to the method of the invention contains titanium dioxide in the range of 6% by wt. to 12% by wt., which corresponds to a titanium content of 3.6% by wt. to 7.2% by wt. If soot particles are used that at less than 120 wt. ppm have a small amount of OH groups, these cannot make any significant contribution to the oxidation of Ti³⁺ to Ti^{4±}. Nitrogen oxide, oxygen or ozone is used as the oxidative treatment reagent. If the conditioning treatment is carried out with a nitrogen oxide, such as nitrous oxide (N₂O) or nitrogen dioxide (NO₂), it is possible to carry out the conditioning treatment at temperatures below 600° C. in a graphite furnace, as is otherwise also used for the drying and vitrifying of SiO₂ soot bodies. During the further heating of the graphite furnace to sintering temperature, the gas supply is stopped, with the nitrogen oxide remaining adsorbed on the soot particles and leading there to the oxidation of Ti³⁺ to Ti⁴⁺. The method according to the invention is thus particularly economical when the conditioning treatment is carried out with a nitrogen oxide.

According to the invention, vitrification yields a blank with a mean TiO₂ concentration in the range of 6% by wt. to 12% by wt. and a deviation from the mean value of not more than 0.06% by wt., a mean fluorine concentration in the range of 1,000 wt. ppm to 10,000 wt. ppm, and a deviation from the mean value of not more than 10%, a slope of the coefficient of thermal expansion CTE in the temperature range of 20° C. to 40° C., expressed as differential quotient dCTE/dT between 0.4 and 1.2 ppb/K², and with a local distribution of the CTE, characterized by a deviation from the mean value of less than 5 ppb/K. Such a blank of fluorine-and titanium-doped silica glass produced according to the method of the invention is distinguished by a particularly high homogeneity of the dopant distribution. This optimizes the local distribution of the CTE over the optically used area, also called “CA area” (clear perture). The local distribution of the CTE over the CA area of the blank varies with a deviation from the mean value of less than 5 ppb/K only to a small degree. Moreover, the blank shows a very small slope of the CTE in the temperature range of the application in EUV lithography.

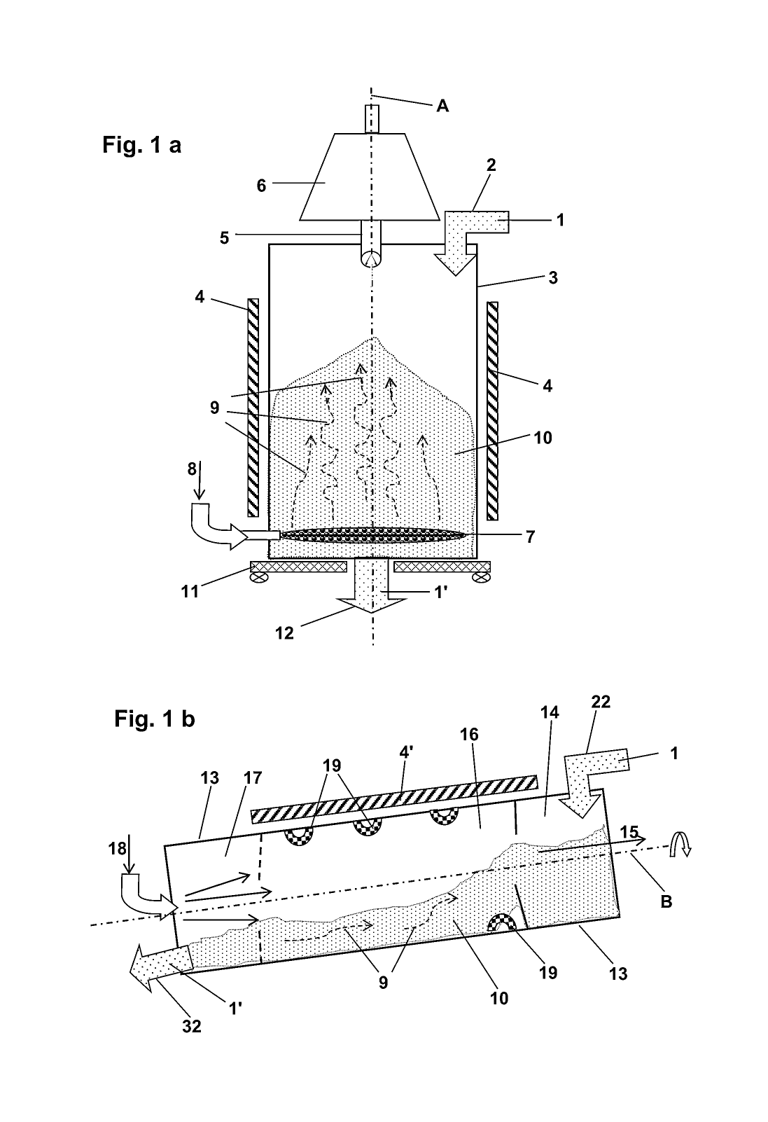

TiO₂—SiO₂soot particles are produced by flame hydrolysis of octamethylcyclotetrasiloxane (OMCTS) and titanium-isopropoxide [Ti(OPrⁱ)₄] as the feedstock and are deposited in a collecting vessel in a process chamber as loose soot particles. The loose soot particles consist of synthetic TiO₂—SiO₂glass doped with about 8% by wt. of TiO₂. As shown in FIG. 1a, the TiO₂—SiO₂soot particles 1 are transferred via a suitable powder supply system 2 into a reaction vessel 3 in which the TiO₂—SiO₂soot particles are doped with fluorine. The reaction vessel 3 has a cylindrical shape with vertically oriented central axis A and is heatable by heating elements 4 arranged outside the vessel. The reaction vessel 3 is sealed at the upper end, except for an opening for an exhaust gas line 5. The exhaust gas line 5 is connected to a dust separator 6. In the lower part of the reaction vessel 3, the TiO₂—SiO₂soot particles 1 form a powder bed 10 as a loose bulk material. A ring shower 7 is positioned at the bottom of the reaction vessel in a direction coaxial to the central axis A, the ring shower 7 comprising numerous nozzle openings from which the fluorine-containing reagent exits and acts on the powder bed 10 of TiO₂—SiO₂soot particles 1 in the form of a substantially laminar gas stream, outlined by the directional arrows 9. The ring shower 7 is connected to a gas circulating pump (not shown) via which the fluorine-containing reagent is supplied. The gas inlet is outlined by the arrow with reference numeral 8. For the batchwise removal of the fluorine-doped TiO₂—SiO₂soot particles 1′, a closable removal nozzle 12 is disposed on the bottom of the reaction vessel. The reaction vessel 3 is mounted on an agitator 11 to possibly cause the movement of the powder bed 10 located in the vessel 3 by way of vibrations.

A batch of 80 kg of the TiO₂—SiO₂soot particles 1 is filled into the reaction vessel 3. The TiO₂—SiO₂soot particles 1 have a mean particle size of 120 nm (D₅₀ value) and a BET specific surface area of about 100 m²/g. SiF₄ is introduced as the fluorine-containing reagent through the ring shower 7 into the powder bed 10 of TiO₂—SiO₂soot particles 1. The flow rate for the fluorine-containing reagent is in the range of 6-8 liters per minute, whereby the TiO₂—SiO₂soot particles 1 are intensively flushed around by the fluorine reagent and the powder bed 10 is thereby slightly swirled. The TiO₂—SiO₂soot particles 1 now react with the fluorine reagent, so that after a treatment period of about five hours at 500° C. of the reaction partners, TiO₂—SiO₂soot particles 1′ which are doped with 4600 wt. ppm fluorine can be taken out of the reaction vessel 3. When the powder bed 10 consisting of TiO₂—SiO₂soot particles 1 is heated by heating the reaction vessel 3 to a temperature of about 1,000° C., the treatment period is shortened to about 30 minutes.

FIG. 1b schematically shows the setup of an apparatus for performing the method according to the invention in a rotary tube 13. The rotary tube 13 is rotating about its longitudinal axis B. The TiO₂—SiO₂soot particles 1 to be fluorinated are fed into the slightly inclined rotary tube 13 in the upper inlet portion 14. In FIG. 1b, a filling device for the TiO₂—SiO₂soot particles 1 to be treated with fluorine is schematically marked with a block arrow with reference numeral 22. According to FIG. 1b the fluorine gas (SiF₄ or CF₄) is supplied at the lower end of the rotary tube 13, i.e., the counter-current principle is applied. The gas inlet is outlined by the arrow with reference numeral 18. The material inlet portion 14 comprises a suction or gas outlet for the fluorine-containing reagent; in FIG. 1b, this is illustrated by the directional arrow with reference numeral 15. The gas stream within the rotary tube 13 is substantially laminar (directional arrows 9), so that a continuous and particularly intensive treatment of the supplied TiO₂—SiO₂soot particles 1 with SiF₄ or CF₄ is achieved. The material outflow portion 17 is positioned at the opposite end of the apparatus, and the process chamber 16 is arranged therebetween. The material outflow portion 17 comprises a material removal device for the fluorine-doped TiO₂—SiO₂soot particles 1′, which is schematically illustrated in FIG. 1b with a block arrow with reference numeral 32. The rotary tube 13 is heated by a heating element 4′ to the desired process temperature. The inflowing fluorine-containing gas may additionally be preheated. In the interior of the rotary tube 13, there are shovel-like mixing elements 19 which first receive the soot particles 1 during the rotational movement of the rotary tube 13 and then let them trickle therefrom in the further course. This intensifies the movement of the powder bed 10 positioned in the rotary tube 13.

The TiO₂—SiO₂soot particles 1 are continuously fed into the inlet portion 14 and are there preheated to about 950° C. The total length of the rotary tube 13 is about 250 cm; the diameter is typically 20 cm. The rotary tube 13 has arranged therein mixing elements 19 which thoroughly mix the powder bed 10 consisting of soot particles 1 to be fluorinated, thereby uniformly heating the same. The material inlet portion 14 passes into the process chamber 16, but is separated in part therefrom by a constriction, viewed in cross section, so that the supplied soot particles 1 slightly accumulate before entry into the process chamber 16. This prevents an excessively rapid passage through the material inlet portion 14. In the process chamber 16, the soot particles 1 are flushed around in laminar fashion by the gaseous fluorine reagent, with a temperature being set in the range of about 1,000° C. At this temperature it is possible to achieve a very good fluorination action with the help of the fluorine-containing treatment gas and additionally with the mixing elements 19 disposed in the process chamber 16. The residence time of TiO₂—SiO₂soot particles 1 of a weight of about 40 kg in the process chamber 16 is about 2 hours. The gas supplies (directional arrow 18) of SiF₄ or CF₄ are led through the material outflow portion 17. The treatment gas is thereby preheated by the residual heat of the already fluorinated TiO₂—SiO₂soot particles 1′ in the material outflow portion 17 to about 500° C. before it enters into the process chamber 16. After having passed through the process chamber 16, the TiO₂—SiO₂soot particles 1 are conveyed into the material outflow portion 17 in which they can be subjected, if necessary, to an after treatment with supply of a further halogen-containing gas.

The throughput of the soot particles 1 to be fluorinated is improved in the continuous process with the rotary tube 13 as compared to the batchwise process by about 20%.

After removal of the fluorine-doped TiO₂—SiO₂soot particles, these are consolidated into granulate. For the granulation, a process is suitable in which the fluorinated TiO₂—SiO₂soot particles are stirred into an aqueous dispersion in a stirring tank by intensive stirring and are homogenized. The aqueous dispersion may contain additives which improve the wettability of the fluorinated TiO₂—SiO₂soot particles. Subsequently, at a relatively low rotational speed, a nitrogen stream heated to about 100° C. acts on the dispersion. Moisture is thereby removed, resulting in a substantially pore-free TiO₂—SiO₂granulate in the stirring tank as an agglomerate of fluorinated TiO₂—SiO₂soot particles. As an alternative to this granulation method, the aqueous dispersion may also be sprayed in a hot air stream with formation of a spray granulate. The granulates are well suited for further processing in a dry pressing process. However, it is also possible to first vitrify the granulates into grains, which is only then followed by a shaping process for the formation of the blank.

For the manufacture of a blank in the form of a plate having a diameter of about 36 cm and a thickness of about 6 cm, the granulate is filled into a mold and isostatically processed at a pressure of 100 MPa into a pressed item. The dimensions of the mold take into account the shrinkage in the subsequent vitrification of the pressed item (“near-net-shape technique”), so that shaping is possible without any further forming steps. The pressed item produced thereby is thermally dried in a drying cabinet, and then converted in the sintering furnace where first a conditioning treatment at 600° C. in an atmosphere of nitrous oxide (N₂O) follows. During this conditioning treatment, a large part, if possible, of the Ti³⁺ ions is converted into Ti⁴⁺ ions, which enhances the transparency of the blank to be produced from the fluorinated TiO₂—SiO₂soot particles 1′ in the visible spectral range. Subsequently, the pressed item is first pre-sintered at 1,600° C. in He atmosphere and then vitrified at about 1,800° C. This creates a slightly brownish-colored plate-shaped blank of titanium-doped glass having a high silicic-acid content with a predetermined fluorine content. The distribution of the titanium and the fluorine in the blank is particularly homogeneous owing to the application of the method according to the invention. Possible subsequent homogenization measures, which are otherwise common, can here be omitted.

The blank produced according to the invention from fluorine-doped TiO₂—SiO₂glass with a diameter of 30 cm and a thickness of 5.7 cm is subjected to an annealing treatment to remove mechanical stresses and to set a predetermined fictive temperature. The blank is here heated in air and at atmospheric pressure to 950° C. during a hold time of 8 hours, and is subsequently cooled at a cooling rate of 4° C./h to a temperature of 800° C. and held at that temperature for 4 hours. Thereupon, the TiO₂—SiO₂blank is cooled at a higher cooling rate of 50° C/h to a temperature of 300° C., whereupon the furnace is shut off and the blank is allowed to cool freely in the furnace.

For further processing and for the determination of the properties of the blank a thin surface layer is removed from the blank, which layer has been damaged by the previous process steps. A plane side is polished, resulting in a diameter of 29.5 cm and a thickness d of 5 cm for the blank.

The blank obtained thereby consists of particularly homogenized fluorine-doped TiO₂—SiO₂glass containing 7.7% by wt. of titanium dioxide and 4600 wt. ppm fluorine. The mean fictive temperature measured over the total thickness is 820° C.

The fictive temperature of a comparative material designated as V1 and consisting of TiO₂—SiO₂glass, but without fluorine doping, is 960° C. higher than in the blank produced according to the invention.

A common measuring method for determining the fictive temperature on the basis of a measurement of the Raman scattering intensity at a wave number of about 606 cm⁻¹ is described in Ch. Pfleiderer et. al.; “The UV-induced 210 nm absorption band in fused silica with different thermal history and stoichiometry;” Journal of Non-Cryst. Solids 159 (1993), pp. 143-145.

Moreover, for the blank produced according to the method of the invention and for the comparative material, the mean thermal expansion coefficient is determined by interferometry on the basis of the method as described in R. Schodel, “Ultra-high accuracy thermal expansion measurements with PTB's precision interferometer” Meas. Sci. Technol. 19 (2008) 084003 (11 pp). In the blank produced according to the invention, a zero crossing temperature (T_{ZC}) of 28° C. and a variation of the CTE of 2ppb/k is detected.

For the comparative material V1, the T_{ZC} is 25° C. and the coefficient of thermal expansion CTE varies with about 6 ppb/K. With these properties, the comparative material V1 is no longer adapted to meet the high demands made on image quality in EUV lithography, but can still be called adequate for other selected applications, for instance as a material for the production of measurement standards or as a substrate material for large astronomical mirrors.

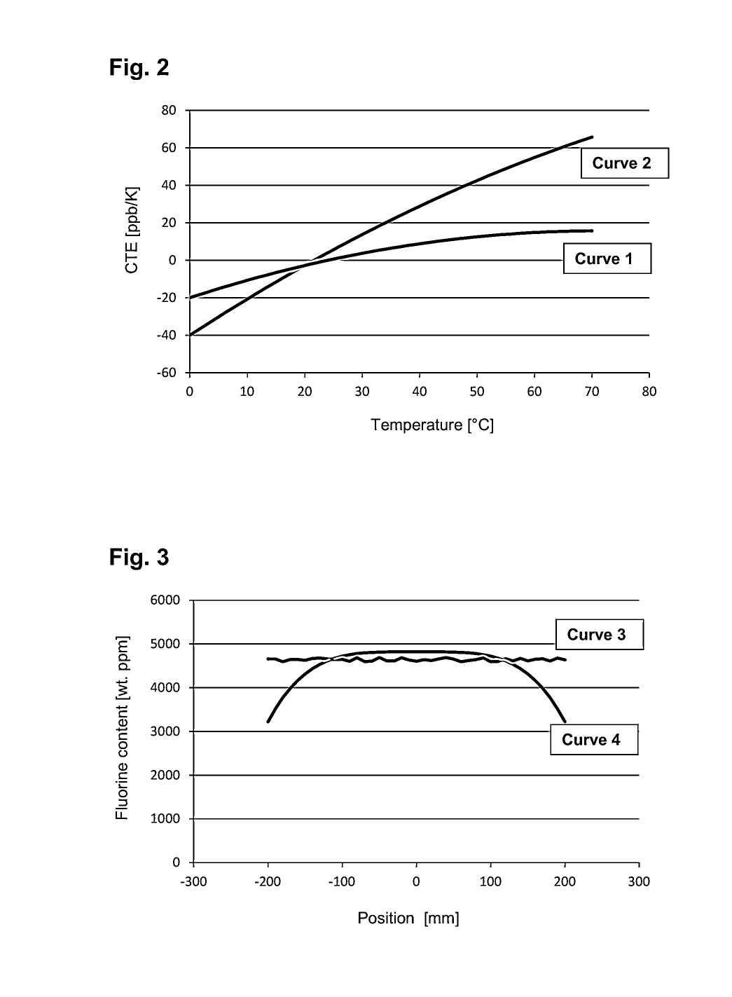

The diagram of FIG. 2 shows the coefficient of thermal expansion CTE as a function of the temperature. Curve 1 shows a particularly flat profile of the CTE for the fluorine-doped TiO₂—SiO₂blank produced according to the method of the invention. The slope of the CTE is 0.75 ppb/K² in the temperature range of 20° C. to 40° C. In comparison, FIG. 2, curve 2, shows a very steep profile of the CTE against the temperature for the comparative material V1 of a TiO₂—SiO₂glass with a titanium-dioxide content of 7.4% by wt., but without fluorine doping. The slope of the CTE is 1.6 ppb/K² for the comparative material V1 in the temperature range of 20° C. to 40° C.

The diagram of FIG. 3 shows the local fluorine distribution of a blank produced according to the method of the invention (curve 3) and, for comparison, a comparative material V2 (curve 4). The measurement values on which the curves are based are determined in the optically used area, so-called “CA area”, at positions of a 50-100 mm distance from one another.

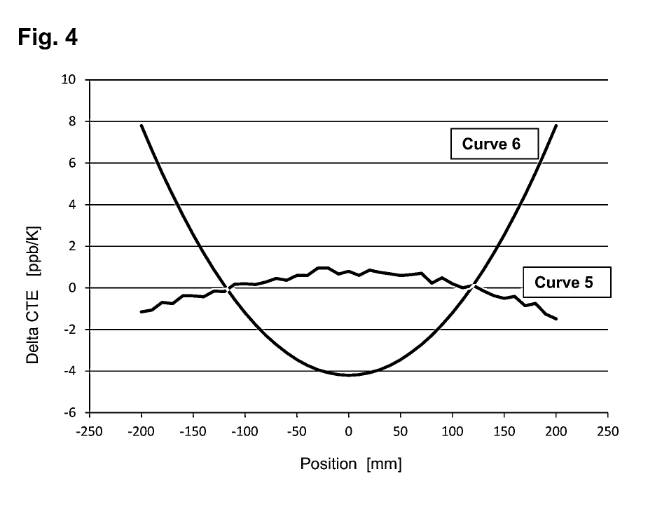

The comparative material V2 starts from a TiO₂—SiO₂soot body (not soot particles) which has been doped with fluorine by a gas stream of 20% SiF₄ acting on the soot body at 800° C. in helium for 3 hours. This was followed by a vitrification step at about 1,400° C. to form a preform. Mechanical homogenization of the vitrified preform and shaping into a TiO₂—SiO₂blank were followed by an annealing treatment by analogy with the blank produced according to the invention. Thus, the fictive temperature is also about 820° C. The mean titanium-oxide content and fluorine content of the comparative material V2 are 7.7% by wt. and 4600 wt. ppm, respectively, as in the blank produced according to the invention. Thus, as for the slope of the CTE against the temperature, one obtains approximately a value with the same order of magnitude as in the blank produced according to the invention. By contrast, however, the homogeneity with respect to the fluorine distribution and the local variation of the CTE (see FIG. 4) is relatively poor in the comparative material V2.

The action of fluorine on a TiO₂—SiO₂soot body is irregular because the temperature of the soot body may be different in sub-regions and the structure of the soot body puts up a certain resistance to the diffusion of the fluorine reagent. For instance, sub-regions of the soot body may more or less come into contact with the fluorine reagent. Moreover, there is the risk that process steps subsequent to the fluorine treatment lead again to a decrease in the fluorine content in the outer volume regions of the (possibly further densified) soot body. This yields the bell-shaped distribution of the fluorine in the blank, as shown with curve 4.

This risk does not exist in the method according to the invention with a fluorination of the TiO₂—SiO₂soot particles. Rather, it becomes apparent (curve 3) that the method according to the invention with a fluorine doping of the soot particles leads to a very homogeneous fluorine distribution in the blank.

FIG. 4 shows the local distribution of the mean value deviation of the CTE (delta CTE) in the CA area of the fluorine-doped TiO₂—SiO₂blank produced according to the method of the invention (curve 5) and, by comparison, for the blank from the comparative material V2 (curve 6). The very homogeneous fluorine distribution shown in FIG. 3 correlates in FIG. 4 with an equally homogeneous local distribution for the mean value deviation of the CTE of the blank produced according to the invention.

By contrast, the local distribution of the delta CTE of the comparative material V2 shows considerable deviations for the CTE of up to 12 ppb/K, particularly in the edge regions of the optically used area. The material V2 is therefore not suited for use in EUV lithography because such a material would lead to image errors and is thus unacceptable.

The essential characteristics of the blank produced according to the method of the invention in comparison with comparative material V1 and V2 are hereinafter summarized in a table.

| | Blank of the method | Comparative | Comparative |
|---|---|---|---|
| | according to the | material | material |
| Characteristics | invention | V1 | V2 |
| Titanium oxide | 7.7 | 7.4 | 7.7 |
| content | | | |
| [wt.-%] | | | |
| Fluorine content | 4600 | 0 | 4600 |
| [wt.-ppm] | | | |
| Fictive temp. | 820 | 960 | 820 |
| [° C.] | | | |
| ΔCTE/ΔT | 0.75 | 1.6 | about 0.75 |
| [ppb/K²] | | | |
| Variation of CTE | 2 | 6 | 12 |
| [ppb/K] | | | |
| Homogeneity | very good | possibly sufficient | poor |

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-13. (canceled)

14. A method for producing a blank from titanium-doped glass having a high silicic-acid content with a predetermined fluorine content for use in EUV lithography, the method comprising forming TiO₂—SiO₂soot particles by flame hydrolysis of silicon-and titanium-containing precursor substances, and exposing the TiO₂—SiO₂soot particles in a moved powder bed to a fluorine-containing reagent to convert the TiO₂—SiO₂soot particles into fluorine-doped TiO₂—SiO₂soot particles, wherein the fluorine-doped TiO₂—SiO₂soot particles are consolidated and verified vitrified into the blank.

15. The method according to claim 14, wherein the silicon-containing precursor substance is octamethylcyclotetrasiloxane (OMCTS) and the titanium-containing precursor substance is titanium isopropoxide [Ti(OPri)₄].

16. The method according to claim 14, wherein the TiO₂—SiO₂soot particles have a mean particle size in a range of 20 nm to 500 nm and a BET specific surface area in a range of 50 m²/g to 300 m²/g.

17. The method according to claim 14, wherein a TiO₂ content of the fluorine-doped TiO₂—SiO₂soot particles is set in a range of 6% by wt. to 12% by wt.

18. The method according to claim 14, wherein a fluorine content of the fluorine-doped TiO₂—SiO₂soot particles is set in a range of 1,000 wt. ppm to 10,000 wt. ppm.

19. The method according to claim 14, wherein the fluorine-containing reagent is selected from SiF₄, CHF₃, CF₄, C₂F₆, C₃F₈, F₂ and SF₆.

20. The method according to claim 14, wherein the moved powder bed is formed as a loose bulk material of the TiO₂—SiO₂soot particles which has the fluorine-containing reagent flowing therethrough and moved thereby.

21. The method according to claim 14, wherein the fluorine-containing reagent acts on the TiO₂—SiO₂soot particles for a duration of at least 5 minutes.

22. The method according to claim 14, wherein the powder bed is heated to a temperature ranging from room temperature to 1100° C.

23. The method according to claim 20, wherein the movement of the powder bed includes a mechanical action.

24. The method according to claim 14, wherein the consolidation of the fluorine-doped TiO₂—SiO₂soot particles is carried out by granulation and/or pressing.

25. The method according to claim 14, further comprising prior to vitrification, subjecting the fluorine-doped TiO₂—SiO₂soot particles to a conditioning treatment which comprises an oxidizing treatment with a nitrogen oxide, oxygen, or ozone.

26. The method according to claim 14, wherein the blank obtained during vitrification has a mean TiO₂ concentration in the range of 6% by wt. to 12% by wt. and a deviation from the mean value of not more than 0.06% by wt., a mean fluorine concentration in the range of 1,000 wt. ppm to 10,000 wt. ppm, and a deviation from the mean value of not more than 10%, a slope of the coefficient of thermal expansion CTE in the temperature range of 20° C. to 40° C., expressed as differential quotient dCTE/dT between 0.4 and 1.2 ppb/K2, and a local distribution of the CTE, characterized by a deviation from the mean value of less than 5 ppb/K.
